(19) United States
(12) Patent Application Publication
(10) Pub. No.: US 2009/0095996 A1
(43) Pub. Date: Apr. 16, 2009

(54) Semiconductor device

(75) Inventors: Won-Woong Chung, Yongin-si (KR); Young-Min Kang, Seoul (KR)

Correspondence Address: HARNESS, DICKEY & PIERCE, P.L.C., P.O. BOX 8910, RESTON, VA, 20195, US

(73) Assignee: Samsung Electronics Co, Ltd.

(21) Appl. No.: 12/285,525

(22) Filed: Oct. 8, 2008

(30) Foreign Application Priority Data
Oct. 10, 2007 (KR) 10-2007-0101871

(51) Int. Cl. H01L 27/115; H01L 29/92

(52) U.S. Cl. 257/296; 257/E29.342; 257/E27.103

(57) ABSTRACT

A semiconductor device includes a substrate including an active region, a first impurity region, second impurity regions, a word line and a bit line. The active region has end portions extending in a first direction and a central portion extending in a second direction inclined relative to the first direction. The first impurity region is disposed at the central portion, and the second impurity regions are disposed at the end portions. The word line extends in a third direction substantially perpendicular to the first direction. The bit line extends in the first direction. The bit line is electrically connected to the first impurity region. The second impurity regions may be symmetrical to each other centering adjacent two word lines and adjacent one bit line. The semiconductor device may have improved sensing margin by reducing the capacitance of the bit line.

### BACKGROUND

1. Field

Example embodiments relate to a semiconductor device and a method of manufacturing a semiconductor device. More particularly, example embodiments relate to a semiconductor device including an active region, a word line and a bit line extending different directions, and a method of manufacturing the semiconductor device.

2. Description of the Related Art

Semiconductor memory devices are generally classified into volatile semiconductor devices such as dynamic random access memory (DRAM) devices or static random access memory (SRAM) devices, and non-volatile semiconductor devices, for example, erasable programmable read only memory (EPROM) devices, electrically erasable programmable read only memory (EEPROM) devices, flash memory devices, etc. The volatile semiconductor memory devices may lose stored data when applied power is off. However, stored data may be maintained in the non-volatile semiconductor memory device even though applied power is off.

In the meantime, a ferroelectric random access memory (FRAM) device has characteristics of the volatile and the non-volatile semiconductor memory devices, so that the FRAM device may have wide possibility of employment in various electric and electronic apparatuses. Although the FRAM device has a response speed substantially lower than that of the volatile semiconductor device, the response speed of the FRAM device may be faster than that of the non-volatile semiconductor device by about 10⁴ to about 10⁵ times. Since the ferroelectric material in the FRAM device has spontaneous polarization, data stored in the FRAM device may be maintained even though applied power gives out. Additionally, the FRAM device may have a voltage of about 2V to about 5V to cause the inversion of polarization of the ferroelectric material, so that the FRAM device may operate with a low voltage in comparison with the EPROM device or the EEPROM device operating with a voltage of about 10V to about 12V. Furthermore, the FRAM device may have durability greater than that of the non-volatile semiconductor memory device.

The FRAM device such as a capacitor type FRAM device or a field effect transistor type FRAM device usually includes a memory cell having one transistor and one capacitor. FIG. 1 illustrates an equivalent circuit diagram of a conventional FRAM device.

As shown in FIG. 1, the FRAM device includes a transistor 1 having a word line 3, a ferroelectric capacitor 2, a bit line 4, and an upper wiring 5. The ferroelectric capacitor 2 is electrically connected to a drain region of the transistor 1, and the bit line 4 is electrically connected to a source region of the transistor 1. The upper wiring 5 makes electrical contact with the ferroelectric capacitor 2.

As the FRAM device has been highly integrated, the sensing margin (ΔV) of the FRAM device becomes more important to ensure the stable operation of the FRAM device. Generally, the sensing margin (ΔV) of the FRAM device is proportional to the capacitance of the capacitor (Cs) and inversely proportional to the capacitance of the bit line (Cb). Here, the capacitance of the capacitor (Cs) is equal to 2Pr×Acap, wherein Pr denotes the polarization of the ferroelectric material in the FRAM device, and Acap means the effective area of the capacitor. Thus, the sensing margin (ΔV) of the FRAM device may be improved by increasing the capacitor capacitance (Cs) and/or by reducing the bit line capacitance (Cb). To increase the capacitance (Cs) of the capacitor, the capacitor has a three-dimensional structure or the ferroelectric material has high remnant polarization. Further, the capacitance of the bit line (Cb) is reduced so as to enhance the sensing margin (ΔV) of the FRAM device.

The conventional FRAM device has a folded bit line structure that includes two word lines in one memory cell. This FRAM device having the folded bit line structure is discloses at Korean Patent No. 476,397. According to the Korean Patent, the memory cell of the FRAM device includes transistors having word lines, a bit line connected to source regions of the transistors, and a capacitor connected to common drain region of the transistors. However, the coupling noise of the memory cell of the FRAM device may sometimes occur, so that data stored in the FRAM device may be easily vanished due to the coupling noise. Further, the capacitance of the bit line may not be properly reduced because two word lines are disposed in one memory cell. As a result, the FRAM device having the folded bit line structure may not ensure desired sensing margin.

### SUMMARY

This application claims priority under 35 U.S.C. §119 to Korean patent Application No. 2007-101871, filed on Oct. 10, 2007 in the Korean Intellectual Property Office (KIPO), the contents of which are herein incorporated by reference in their entirety.

Example embodiments provide a semiconductor having enhanced integration degree and reduced bit line capacitance by properly disposing an active region, a word line and a bit line.

Example embodiments provide a method of manufacturing a semiconductor device high integration degree and small bit line capacitance by properly disposing an active region, a word line and a bit line.

According to one aspect of example embodiments, there is provided a semiconductor device including a substrate including an active region, a first impurity region, second impurity regions, a word line and a bit line. The active region includes end portions and a central portion. The end portions of the active region extend in a first direction and the central portion of the active region is prolonged along a second direction substantially inclined relative to the first direction. The word line extends along a third direction substantially perpendicular to the first direction. The first impurity region is disposed at the central portion of the active region, and the second impurity regions are disposed at the end portions of the active region. The bit line extends in the first direction. The bit line is electrically connected to the first impurity region.

In example embodiments, the second impurity regions may be symmetrically disposed centering one bit line. Further, the second impurity regions may be symmetrically disposed centering two adjacent word lines.

In example embodiments, an insulating interlayer may be disposed between the word line and the bit line. Additionally, a contact pad making contact with the first impurity region may be formed through the insulation interlayer.

In example embodiments, an additional insulation interlayer may be disposed on the bit line. A contact plug making contact with the second impurity region may be formed through the additional insulation interlayer. A capacitor may be disposed on the additional insulation interlayer and the contact plug.

In example embodiments, two contact plugs may be symmetrically disposed centering two adjacent word lines and one bit line.

In example embodiments, the word line may include a gate insulation layer pattern on the substrate, a gate electrode on the gate insulation layer pattern and a gate mask on the gate electrode.

According to another aspect of example embodiments, there is provided a semiconductor device including a substrate having an active region, a first impurity region, second impurity regions, a word line and a bit line. The active region includes a first portion extending along a first direction, a second portion extending along a second direction substantially inclined relative to the first direction, and a central portion between the first and the second portions. The first impurity region is disposed at the central portion of the active region, and the second impurity regions are disposed at ends of the first and the second portions of the active region. The word line extends along a third direction substantially inclined relative to the first and the second directions. The bit line extends along a fourth direction substantially perpendicular to the third direction. The bit line is electrically connected to the first impurity region.

In example embodiments, the second impurity regions may be symmetrically disposed centering two adjacent word lines and one bit line. Further, the active region may be symmetrical to an adjacent active region centering the bit line.

In example embodiments, the ends of the first and the second portions of the active region may be symmetrical to each other centering two adjacent word lines.

In example embodiments, a contact pad may be disposed on the first impurity region, and a first insulation interlayer may be disposed on the contact pad and the word line. A second insulation interlayer may be disposed on the first insulation interlayer and the first insulation interlayer. A bit line contact pad may be disposed on the contact pad through the second insulation interlayer.

In example embodiments, a third insulation interlayer may be disposed on the bit line and the second insulation interlayer. A contact plug may be disposed on the second impurity region through the first, the second and the third insulation interlayers. A capacitor may be disposed on the contact plug and the third insulation interlayer.

According to still another aspect of example embodiments, there is provided a method of manufacturing a semiconductor device. In the method of manufacturing the semiconductor device, an active region is defined on a substrate. The active region has end portions extending in a first direction and a central portion extending a second direction inclined relative to the first direction. A word line is formed on the substrate. The word line extends along a third direction substantially perpendicular to the first direction. First and second impurity regions are formed at the central and the end portions of the active region, respectively. A bit line is formed over the word line. The bit line extends in the first direction and makes electrical contact with the first impurity region.

In the formation of the word line according to example embodiments, a gate insulation layer pattern may be formed on the substrate, and then a gate electrode may be formed on the gate insulation layer pattern. A gate mask may be formed on the gate electrode.

In example embodiments, adjacent second impurity regions may be symmetrical to each other centering adjacent two word line. Further, adjacent second impurity regions may be symmetrical to each other centering adjacent one bit line.

In example embodiments, a contact pad may be formed on the first impurity region. A bit line contact pad may be formed between the contact pad and the bit line. A contact plug may be formed on the second impurity region. A capacitor may be formed on the contact plug.

According to still another aspect of example embodiments, there is provided a method of manufacturing a semiconductor device. In the method of manufacturing the semiconductor device, an active region is defined on a substrate. The active region has a first portion extending along a first direction, a second portion extending along a second direction inclined relative to the first direction, and a central portion between the first and the second portions. A word line is formed on the substrate. The word line extends along a third direction inclined relative to the first and the second directions. A first impurity region is formed at the central portion of the active region. Second impurity regions are formed at ends of the first and the second portions of the active region. A bit line is formed over the word line. The bit line extends in a fourth direction substantially perpendicular to the third direction and makes electrical contact with the first impurity region. Adjacent second impurity regions may be symmetrical to each other centering adjacent two word line and adjacent one bit line.

According to example embodiments, the second impurity regions may be symmetrically disposed centering two adjacent word lines and one adjacent bit line. This construction of the semiconductor device having the construction may be referred to as an opened bit line structure type semiconductor device. Since the semiconductor device has the opened bit line structure, the distance between adjacent bit lines may be reduced whereas the distance between adjacent word lines may be increased. Therefore, the semiconductor device may have reduced bit line capacitance, and thus may have improved sensing margin.

### BRIEF DESCRIPTION OF THE DRAWINGS

Example embodiments will be will become more apparent by describing in detailed thereof with reference to the accompanying drawings, in which:

FIG. 1 is a circuit diagram illustrating an equivalent circuit of a semiconductor device in accordance with example embodiments;

FIGS. 2, 4, 6, 8 and 10 are plane views illustrating a method of manufacturing a semiconductor device in accordance with example embodiments;

FIGS. 3, 5, 7, 9, 11, 12 and 13 are cross-sectional views illustrating the method of manufacturing the semiconductor device in accordance with example embodiments;

FIG. 14 is a plan view illustrating a method of manufacturing a semiconductor device in accordance with example embodiments; and

FIG. 15 is a graph illustrating capacities of capacitors in a conventional semiconductor device and a semiconductor device according to example embodiments.

### DESCRIPTION OF EMBODIMENTS

The example embodiments are described more fully hereinafter with reference to the accompanying drawings. The invention may, however, be embodied in many different forms and should not be construed as limited to the example embodiments set forth herein. Rather, these example embodiments are provided so that this disclosure will be thorough and complete, and will fully convey the scope of the invention to those skilled in the art. In the drawings, the sizes and relative sizes of layers and regions may be exaggerated for clarity.

It will be understood that when an element or layer is referred to as being “on,” “connected to” or “coupled to” another element or layer, it can be directly on, connected or coupled to the other element or layer or intervening elements or layers may be present. In contrast, when an element is referred to as being “directly on,” “directly connected to” or “directly coupled to” another element or layer, there are no intervening elements or layers present. Like or similar reference numerals refer to like or similar elements throughout. As used herein, the term “and/or” includes any and all combinations of one or more of the associated listed items.

It will be understood that, although the terms first, second, third etc. may be used herein to describe various elements, components, regions, layers, patterns and/or sections, these elements, components, regions, layers, patterns and/or sections should not be limited by these terms. These terms are only used to distinguish one element, component, region, layer pattern or section from another region, layer, pattern or section. Thus, a first element, component, region, layer or section discussed below could be termed a second element, component, region, layer or section without departing from the teachings of example embodiments.

Spatially relative terms, such as “beneath,” “below,” “lower,” “above,” “upper” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

The terminology used herein is for the purpose of describing particular example embodiments only and is not intended to be limiting of the invention. As used herein, the singular forms “a,” “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof.

Example embodiments are described herein with reference to cross-sectional illustrations that are schematic illustrations of illustratively idealized example embodiments (and intermediate structures) of the invention. As such, variations from the shapes of the illustrations as a result, for example, of manufacturing techniques and/or tolerances, are to be expected. Thus, example embodiments should not be construed as limited to the particular shapes of regions illustrated herein but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and will not be interpreted in an idealized or overly formal sense unless expressly so defined herein.

FIGS. 2 to 13 are cross-sectional views and plan views illustrating a semiconductor device in accordance with example embodiments. In FIGS. 2 to 13, although a ferroelectric semiconductor memory device is illustrated, the features of the invention may be easily employed in other semiconductor devices, for example, a dynamic random access memory (DRAM) device, a static random access memory (SRAM) device, a flash memory device, a phase change memory device, etc.

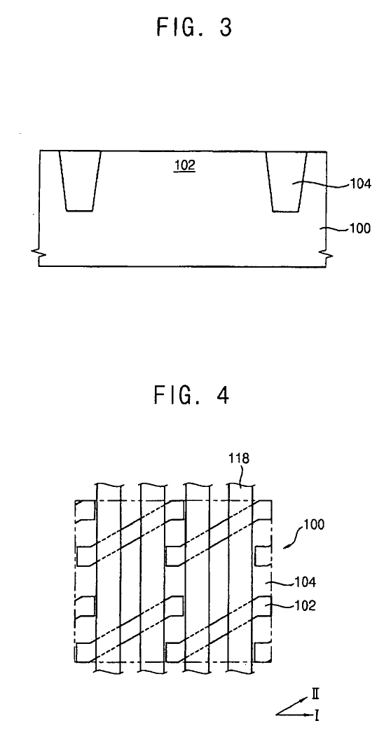

FIG. 2 is a plan view illustrating a substrate 100 of a semiconductor device in accordance with example embodiments, and FIG. 3 is a cross-sectional view illustrating the substrate 100 taken along a second direction II in FIG. 2.

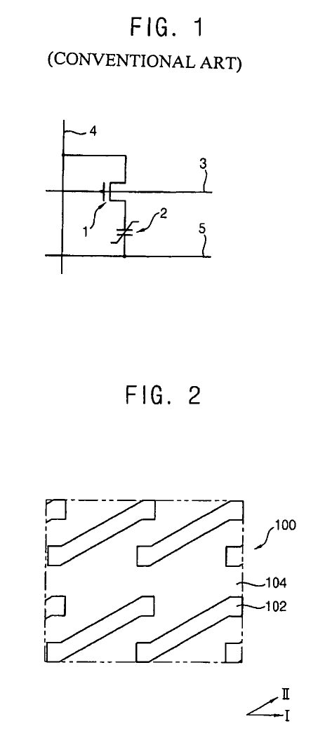

Referring to FIGS. 1 and 2, an isolation layer 104 is provided on the substrate 100 to define the active region 102. The substrate 100 may include a semiconductor substrate, for example, a silicon substrate, a germanium substrate, a silicon germanium substrate, etc. Alternatively, the substrate 100 may include a silicon on insulator (SOI) substrate or a germanium on insulator (GOI) substrate.

The isolation layer 104 may be formed using an oxide such as silicon oxide. For example, the isolation layer 104 may include undoped silicate glass (USG), spin on glass (SOG), flowable oxide (FOX), fluorosilicate glass (FSG), tetraethyl ortho silicate (TEOS), plasma enhanced-tetra ethyl ortho silicate (PE-TEOS), high density plasma-chemical vapor deposition (HDP-CVD) oxide, etc. The isolation layer 104 may be formed by a shallow trench isolation process.

In example embodiments, a first portion of the substrate 100 surrounded by the isolation layer 104 may correspond to the active region 102, and a second portion of the substrate 100 on which the isolation layer 104 is positioned may correspond to a field region. The active region 102 may include a first end portion, a second end portion and a central portion. The central portion of the active region 102 may be prolonged in the second direction II. The first and the second end portions of the active region 102 may extend along a first direction I. The second direction II may be a substantially diagonal direction with respect to an end of the substrate 100. The first direction I may be a substantially parallel direction relative to the end of the substrate 100. Hence, the second direction II may be inclined with respect to the first direction I by a predetermined angle.

The first end portion of the active region 102 may be adjacent to a second end portion of an adjacent active region 102, whereas the second end portion of the active region 102 may be positioned near a first end portion of an adjacent active region 102. In example embodiments, a plurality of active regions 102 may be symmetrically arranged on the substrate 100.

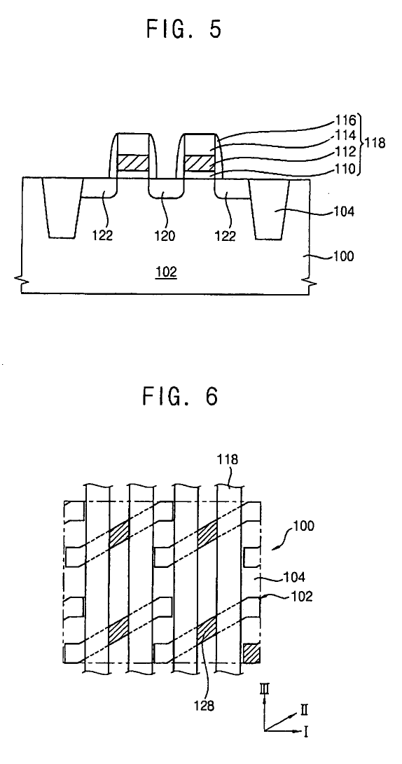

FIG. 4 is a plane view illustrating a word line 118 formed on the substrate 100 in FIG. 2, and FIG. 5 is a cross-sectional view illustrating the word line 118 provided on the substrate 100 in FIG. 3.

Referring to FIGS. 3 and 4, a gate insulation layer (not illustrated) is formed on the substrate 100. The gate insulation layer may have a thin thickness measured from an upper face of the substrate. In example embodiments, the gate insulation layer may be formed using an oxide such as silicon oxide by a chemical vapor deposition (CVD) process, a thermal oxidation process, etc. Alternatively, the gate insulation layer may be formed using a metal oxide that has a dielectric constant substantially higher than that of silicon oxide. For example, the gate insulation layer may include hafnium oxide (HfOx), zirconium oxide (ZrOx), aluminum oxide (AlOx), tantalum oxide (TaOx), etc. Here, the gate insulation layer may be formed by a CVD process, an atomic layer deposition (ALD) process, a sputtering process, an evaporation process, etc.

A first conductive layer (not illustrated) is formed on the gate insulation layer. The first conductive layer may be formed using polysilicon, a metal and/or a metal compound. For example, the first conductive layer may include polysilicon doped with impurities, tungsten (W), titanium (Ti), aluminum (Al), tantalum (Ta), copper (Cu), tungsten nitride (WNx), titanium nitride (TiNx), aluminum nitride (AlNx), titanium aluminum nitride (TiAlxNy), tantalum nitride (TaNx), tungsten silicide (WSix), cobalt silicide (CoSix), titanium silicide (TiSix), etc. These may be used alone or in a mixture thereof.

In example embodiments, the first conductive layer may have a single layer structure that includes a polysilicon film, a metal film, a metal nitride film or a metal silicide film. Alternatively, the first conductive layer may have a multi layer structure including a polysilicon film, a metal film, a metal nitride film and/or a metal silicide film.

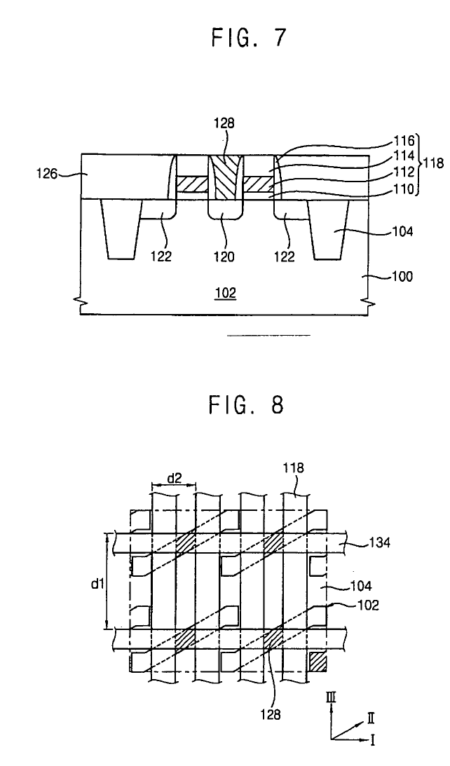

A first mask layer (not illustrated) is formed on the first conductive layer. The first mask layer may be formed using a material that has an etching selectivity relative to the first conductive layer and a first insulation interlayer 126 (see FIG. 7). For example, the first mask layer may include a nitride such as silicon nitride or an oxynitride such as silicon oxynitride. In example embodiments, the first mask layer may be formed using silicon nitride when the first insulation layer 126 includes silicon oxide.

After forming a first photoresist pattern (not illustrated) is provided on the first mask layer, the first mask layer is etched to form a gate mask 114 on the first conductive layer. Using the gate mask 114 as an etching mask, the first conductive layer and the gate insulation layer are sequentially etched, so that a gate insulation layer pattern 110 and a gate electrode 112 are formed between the substrate 100 and the gate mask 115. Therefore, a word line 118 of the semiconductor device is provided on the substrate 100. The word line 118 includes the gate insulation layer pattern 110, the gate electrode 112 and the gate mask 114. Here, the gate insulation layer pattern 110 may be positioned in the active region 102 of the substrate 100.

In some example embodiments, the first mask layer, the first conductive layer and the gate insulation layer may be successively etched using the first photoresist pattern as an etching mask, thereby forming the word line 118 on the substrate 100. The first photoresist pattern may be removed from the gate mask 114 by a stripping process and/or an etch-back process. Alternatively, the first photoresist pattern may be consumed while forming the word line 118 on the substrate 100.

The word line 118 further includes a gate spacer 116 provided on sidewalls of the gate mask 114, the gate electrode 112 and the gate insulation layer pattern 110. In the formation of the gate spacer 116, a first spacer formation layer (not illustrated) may be formed on the substrate 100 to cover the gate mask 114. The first spacer formation layer may be conformally formed along profiles of the gate mask 114, the gate electrode 112 and the gate insulation layer pattern 110. The first spacer formation layer may be formed using a material that has an etching selectivity with respect to the first insulation interlayer 126. For example, the first spacer formation layer may be formed using a nitride such as silicon nitride, or an oxynitride such as silicon oxynitride or titanium oxynitride. Then, the first spacer formation layer is etched to form the gate spacer 116 on the sidewalls of the gate mask 114, the gate electrode 112 and the gate insulation layer pattern 110. The gate spacer 116 may be formed by an anisotropic etching process.

In example embodiments, the word line 118 may extend on the substrate 100 along a third direction III. The third direction III may be substantially perpendicular to the first direction I. Further, the third direction III may be inclined relative to the second direction II by a predetermined angle. That is, the word line 118 may be substantially perpendicular to the first and the second end portions of the active region 102, whereas the word line 118 may be slant with respect to the central portion of the active region 102.

In example embodiments, two word lines 118 may be cross over one active region 102. For example, two word lines 118 may be cross over the central portion of the active region 102 by a predetermined interval. Here, the interval between adjacent word lines 118 may be substantially the same as or substantially similar to a width of the word line 118. When the word line 118 is formed on the substrate 100, a center of the active region 102 is exposed between adjacent word lines 118. Further, the first and the second end portions of the active region 102 are also exposed between adjacent word lines 118.

As illustrated in FIG. 5, a first impurity region 120 is formed at the center of the active region 102, and second impurity regions 122 are formed at the first and the second end portions of the active region 102. The first and the second impurity regions 120 and 122 may be formed by an ion implantation process using the word lines 118 as implantation masks. The first and the second impurity regions 120 and 122 may serve as source/drain regions of a transistor. For example, two transistors may commonly own the first impurity region 120.

In example embodiments, the first impurity region 120 may include a first sub-region and a second sub-region. The first sub-region may be positioned adjacent to the word line 118, and the second sub-region may be provided adjacent to the first sub-region. The first sub-region may have an impurity concentration substantially lower than that of the second sub-region. Further, each of the second impurity regions 122 may also have a third sub-region and a fourth-sub region. The fourth sub-region may have an impurity concentration substantially larger than that of the third sub-region. The third sub-region may be formed beneath the gate spacer 116 of the word line 118, and the fourth sub-region may make contact with the third sub-region.

In some example embodiments, the first and the second impurity regions 120 and 122 may be formed at the center and the end portions of the active region 102 before forming the gate spacer 114 of the word line 118.

FIG. 6 is a plane view illustrating a contact pad 128 formed on the active region 102 in FIG. 4, and FIG. 7 is a cross-sectional view illustrating the contact pad 128 positioned on the active region 102 in FIG. 5.

Referring to FIGS. 6 and 7, the first insulation interlayer 126 is formed on the substrate 100 to cover the word line 118. The first insulation interlayer 126 may have a thickness that sufficiently fills a gap between adjacent word lines 118. The first insulation interlayer 126 may be formed using an oxide such as silicon oxide. For example, the first insulation interlayer 126 may include (BPSG), (PSG), USG, SOG, FOX, FSG, TOSZ, TEOS, PE-TEOS, HDP-CVD oxide, etc. Additionally, the first insulation interlayer 126 may be formed by a CVD process, a PECVD process, a spin coating process, an HDP-CVD process, etc.

In example embodiments, the first insulation interlayer 126 may be planarized so that the first insulation interlayer 126 may have a flat upper face. Here, the first insulation interlayer 126 may be planarized until the gate mask 114 is exposed by a chemical mechanical polishing (CMP) process and/or an etch-back process.

After forming a second photoresist pattern (not illustrated) on the first insulation interlayer 126, the first insulation interlayer 126 is partially etched using the second photoresist pattern as an etching mask to form a first contact hole (not illustrated) that exposes the first impurity region 120. The first contact hole may be formed by an anisotropic etching process.

In example embodiments, the first contact hole may be formed by a self-alignment process. That is, the first contact hole may be self-aligned relative to the gate spacer 116 because the gate spacer 116 has the etching selectivity with respect to the first insulation interlayer 126. The gate mask 114 and the gate spacer 1 16 may protect the gate electrode 112 while forming the first contact hole.

After removing the second photoresist pattern from the first insulation interlayer 126, a second conductive layer (not illustrated) is formed on the first insulation interlayer 126 to fill the first contact hole. The second conductive layer may be formed polysilicon, a metal and/or a metal compound. For example, the second conductive layer may include polysilicon doped with impurities, tungsten, titanium, aluminum, tantalum, copper, titanium nitride, tungsten nitride, aluminum nitride, titanium aluminum nitride, tantalum nitride, etc. These may be used alone or in a mixture thereof. The second conductive layer may be formed by an ALD process, a CVD process, a sputtering process, an evaporation process, etc.

The second conductive layer is removed until the first insulation interlayer 126 is exposed, such that the contact pad 128 is formed in the first contact hole. The contact pad 128 locates on the first impurity region 120 between adjacent word lines 118. The contact pad 128 may be formed through a CMP process and/or an etch-back process.

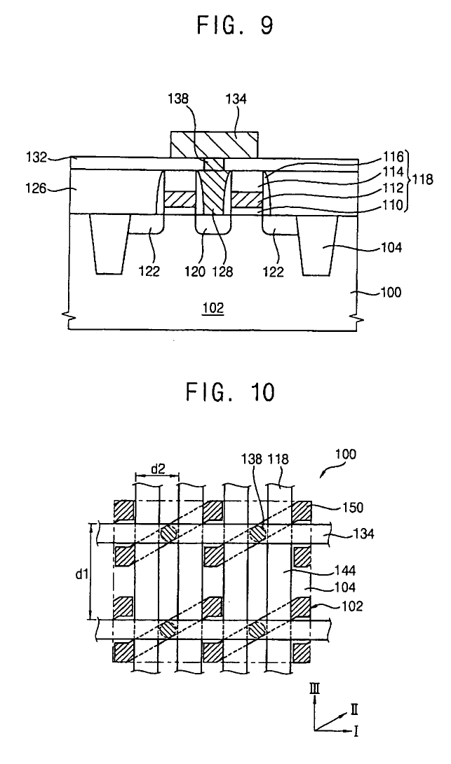

FIG. 8 is a plane view illustrating a bit line 134 formed over the word line 118 in FIG. 6, and FIG. 9 is a cross-sectional view illustrating the bit line 134 positioned over the word line 118 in FIG. 7.

Referring to FIGS. 8 and 9, a second insulation interlayer 132 is formed on the contact pad 128 and the first insulation interlayer 126. The second insulation interlayer 132 may electrically insulate the bit line 134 from the word line 118. The second insulation interlayer 132 may be formed using an oxide by a CVD process, a PECVD process, a spin coating process, an HDP-CVD process, etc. For example, the second insulation interlayer 132 may include BPSG, PSG, USG, SOG, FOX, FSG, TOSZ, TEOS, PE-TEOS, HDP-CVD oxide, etc.

In example embodiments, the second insulation interlayer 132 may include an oxide substantially the same as or substantially similar to that of the first insulation interlayer 126. Alternatively, the first and the second insulation interlayers 126 and 132 may be formed using different oxides, respectively.

A third photoresist pattern (not illustrated) is formed on the second insulation interlayer 132, and then the second insulation interlayer 132 is partially etched using the third photoresist pattern as an etching mask. Hence, a bit line contact hole (not illustrated) is formed through the second insulation interlayer 132. The bit line contact hole exposes the contact pad 128 that locates on the first impurity region 120. The third photoresist pattern may be removed from the second insulation interlayer 132 by an ashing process and/or a stripping process.

A third conductive layer (not illustrated) is formed on the second insulation interlayer 132 to fill the bit line contact hole. The third conductive layer may be formed using polysilicon, a metal and/or a metal compound. For example, the third conductive layer may include polysilicon doped with impurities, tungsten, titanium, aluminum, tantalum, copper, titanium nitride, tungsten nitride, aluminum nitride, titanium aluminum nitride, tantalum nitride, etc. These may be used alone or in a mixture thereof. Further, the third conductive layer may be formed by an ALD process, a CVD process, a sputtering process, an evaporation process, etc.

In example embodiments, a barrier layer (not illustrated) may be additionally formed between the second insulation interlayer 132 and the third conductive layer. The barrier layer may prevent metal in the third conductive layer from diffusing an upward direction and/or a downward direction relative to the substrate 100. The barrier layer may be formed using a metal and/or a metal nitride. For example, the barrier layer may include titanium, titanium nitride, aluminum, aluminum nitride, etc. Here, the barrier layer may be formed by a sputtering process, an ALD process, a CVD process, an evaporation process, etc.

Referring now to FIGS. 8 and 9, a fourth photoresist pattern (not illustrated) is formed on the third conductive layer, and then the third conductive layer is etched to form the bit line 134 and a bit line contact pad 138. That is, the bit line 134 and the bit line contact pad 138 may be simultaneously formed. The bit line contact pad 138 stands on the contact pad 128, and the bit line 134 locates on the bit line contact pad 138 and the second insulation layer 132. Thus, the bit line 134 is electrically connected to the first impurity region 120 through the contact pad 128 and the bit line contact pad 138.

In some example embodiments, the bit line 134 may be formed on the bit line contact pad 138 and the second insulation interlayer 132 after forming the bit line contact pad 138 in the bit line contact hole. Namely, the bit line contact pad 138 and the bit line 134 may be formed through separated processes.

In example embodiments, a bit line mask (not illustrated) may be formed on the bit line 134. The bit line mask may serve as an etching mask for forming the bit line 134. Further, the bit line mask may protect the bit line 134 in successive manufacturing processes. The bit line mask may be formed using a material that has an etching selectivity relative to the bit line 134 and the second insulation interlayer 132. For example, the bit line mask may include silicon nitride or silicon oxynitride.

In example embodiments, the bit line 134 may extend on the second insulation interlayer 132 along the first direction I as illustrated in FIG. 8. That is, the bit line 134 may extend over the active region 102 substantially in parallel relative to the first and the second end portion of the active region 102. Further, the bit line 134 may cross over the central portion of the active region 102 and the word line 118. Thus, the bit line 134 may directly pass over the first impurity region 120.

In example embodiments, a plurality of bit line contact plugs 138 may be provided on the active regions 102 in a matrix structure. Here, two bit line contact pad 138 may be positioned between adjacent bit lines 134 by the one pitch of a memory cell of the semiconductor device. However, one bit line contact pad 138 may be formed between adjacent word lines by the two pitches of the memory cell of the semiconductor device. A first distance D1 between adjacent bit lines 134 along the third direction III may be enlarged in comparison with that of the bit lines in the conventional semiconductor device, such that the loading capacitance of the bit line 134 may be reduced. Additionally, a second distance D2 between adjacent word lines 134 in the first direction I may be reduced in comparison with the word lines of the conventional semiconductor device, so that the number of the bit line contact pad 138 may be decreased. As a result, the semiconductor device may have improved sensing margin while simplifying the constructions of the semiconductor device.

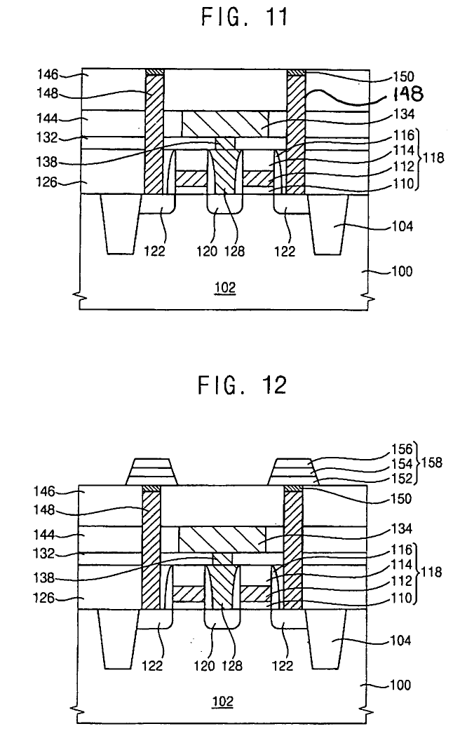

FIG. 10 is a plane view illustrating a contact structure formed on the active region 102 in FIG. 8, and FIG. 11 is a cross-sectional view illustrating the contact structure positioned on the active region 102 in FIG. 9.

Referring to FIGS. 10 and 11, a third insulation interlayer 144 is formed on the second insulation interlayer 132 to cover the bit line 134. The third insulation interlayer 144 may sufficiently fill a gap between adjacent bit lines 134. The third insulation interlayer 144 may be formed using an oxide such as silicon oxide by a CVD process, a spin coating process, a PECVD process, an HDP-CVD process. For example, the third insulation interlayer 144 may include BPSG, PSG, TEOS, PE-TEOS, SOG, USG, FOX, FSG; TOSZ, HDP-CVD oxide, etc.

In example embodiments, the third insulation interlayer 144 may include an oxide substantially the same as or substantially similar to that of the second insulation interlayer 132 and/or that of the first insulation interlayer 126. Alternatively, the first to the third insulation interlayers 126, 132 and 144 may be formed using different oxides, respectively.

In some example embodiments, an upper portion of the third insulation interlayer 144 may be planarized by a planarization process such as a CMP process and/or an etch-back process. Thus, the third insulation interlayer 144 may have a level upper face.

A fourth insulation interlayer 146 is formed on the third insulation interlayer 144 and the bit line 134. The fourth insulation interlayer 146 may be formed using an oxide such as silicon oxide by a CVD process, a spin coating process, a PECVD process, an HDP-CVD process. For example, the fourth insulation interlayer 146 may include BPSG, PSG, TEOS, PE-TEOS, SOG, USG, FOX, FSG, TOSZ, HDP-CVD oxide, etc.

In example embodiments, the fourth insulation interlayer 146 may include an oxide substantially the same as or substantially similar to that of the third insulation interlayer 144, that of the second insulation interlayer 132 and/or that of the first insulation interlayer 126. Alternatively, the first to the fourth insulation interlayers 126, 132, 144 and 146 may be formed using different oxides, respectively.

In some example embodiments, an upper portion of the fourth insulation interlayer 146 may be planarized by a planarization process such as a CMP process and/or an etch-back process. Hence, the fourth insulation interlayer 146 may have a level upper face.

After a fifth photoresist pattern (not illustrated) is provided on the fourth insulation interlayer 146, the fourth to the first insulation interlayers 146, 144, 132 and 126 are partially etched to form a second contact hole (not illustrated). The second contact hole may be formed by an anisotropic etching process. The second contact hole exposes the second impurity region 122. Then, the fifth photoresist pattern may be removed from the fourth insulation interlayer 146 by an ashing process and/or a stripping process.

A fourth conductive layer (not illustrated) is formed on the fourth insulation interlayer 146 to fill the second contact hole. The fourth conductive layer may be formed using a metal, a metal compound and/or doped polysilicon. For example, the fourth conductive layer may include tungsten, tungsten nitride, titanium, titanium nitride, aluminum, aluminum nitride, titanium aluminum nitride, tantalum, tantalum nitride, etc. The fourth conductive layer may be formed by an ALD process, a sputtering process, a CVD process, an evaporation process, etc.

The fourth conductive layer is removed until the fourth insulation interlayer 146 is exposed to form a contact plug 148 is formed in the second contact hole. Thus, the contact plug 148 locates on the second impurity region 122 through the first to the fourth insulation interlayers 126, 132, 144 and 146.

A barrier layer 150 is formed on the contact plug 148, such that the contact structure is provided on the second impurity region 122. That is, the contact structure includes the contact plug 148 and the barrier layer 150. The barrier layer 150 may be formed using a metal nitride by a sputtering process, a CVD process, an ALD process, an evaporation process, etc. For example, the barrier layer 150 may include titanium nitride, tungsten nitride, tantalum nitride, aluminum nitride, etc. These may be used alone or in a mixture thereof.

FIG. 12 is a cross-sectional view illustrating a capacitor formed on the contact structure in FIG 11.

Referring to FIG. 12, a lower electrode layer (not illustrated) is formed on the contact structure and the fourth insulation interlayer 146. The lower electrode layer may be formed using a metal and/or a metal compound by a sputtering process, a pulsed laser deposition (PLD) process, an ALD process, a CVD process, an evaporation process, etc. For example, the lower electrode layer may include iridium (Ir), ruthenium (Ru), platinum (Pt), palladium (Pd), titanium, titanium nitride, iridium oxide (IrOx), strontium ruthenium oxide (SRO), calcium ruthenium oxide (CRO), etc. These may be used alone or in a mixture thereof.

In example embodiments, the lower electrode layer may have a multi layer structure. For example, the lower electrode layer may include a metal nitride film and a metal film. Alternatively, the lower electrode layer may include at least two of a metal nitride film, a metal film and a metal oxide film.

A dielectric layer (not illustrated) is formed on the lower electrode layer. The ferroelectric layer may be formed using a ferroelectric material by a metal organic chemical vapor deposition (MOCVD) process, a sol-gel process, a CVD process, an ALD process, a sputtering process, etc. For example, the dielectric layer may include lead zirconate titanate (PZT), strontium bismuth tantalite (SBT), bismuth lanthanum titanate (BLT), lanthanum doped lead zirconate titanate (PLZT), barium strontium titanate (BST), etc. Alternatively, the dielectric layer may be formed using a metal compound such as hafnium oxide, zirconium oxide, hafnium silicon oxide, zirconium silicon oxide, lanthanum silicon oxide, tantalum oxide, titanium oxide, strontium titanium oxide, etc.

An upper electrode layer (not illustrated) is formed on the dielectric layer. The upper electrode layer may be formed using a metal and/or a metal compound. For example, the upper electrode layer may include iridium, ruthenium, platinum, palladium, titanium, iridium oxide, strontium ruthenium oxide, calcium ruthenium oxide, etc. These may be used alone or in a mixture thereof. Further, the upper electrode layer may be formed by a sputtering process, a pulsed laser deposition (PLD) process, an ALD process, a CVD process, an evaporation process, etc. In example embodiments, the upper electrode layer may have a multi layer structure. For example, the upper electrode layer may include a metal film and a metal film.

After a second mask (not illustrated) is provided on the upper electrode layer, the upper electrode layer, the dielectric layer and the lower electrode layer are etched to form the capacitor 158 on the contact structure and the fourth insulation interlayer 146. The capacitor 158 includes a lower electrode 152, a dielectric layer pattern 154 and an upper electrode 156. The capacitor 158 is electrically connected to the second impurity region 122 through the contact structure.

In example embodiments, the capacitor 159 may have an inclined sidewall. For example, the lower electrode 152 may have an area substantially larger than an area of the dielectric layer pattern 154, and the dielectric layer pattern 156 may also have the area substantially larger than that of the upper electrode 156.

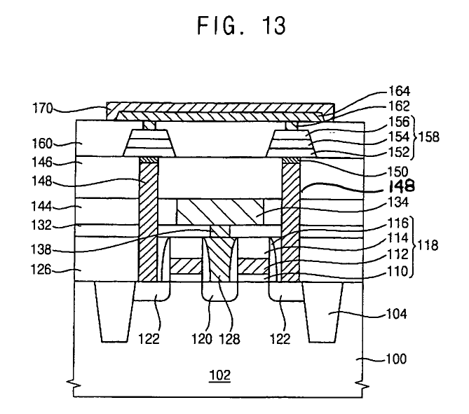

FIG. 13 is a cross-sectional view illustrating a wiring structure formed on the capacitor 158 in FIG. 12.

Referring to FIG. 13, a fifth insulation interlayer 160 is formed on the fourth insulation interlayer 146 to cover the capacitor 158. The fifth insulation interlayer 160 may have a thickness that sufficiently covers the capacitor 158. The fifth insulation interlayer 160 may be formed using an oxide such as silicon oxide by a CVD process, a spin coating process, a PECVD process, an HDP-CVD process. For example, the fifth insulation interlayer 160 may include BPSG, PSG, TEOS, PE-TEOS, SOG, USG, FOX, FSG, TOSZ, HDP-CVD oxide, etc. In example embodiments, the fifth insulation interlayer 160 may include an oxide substantially the same as or substantially similar to that of the fourth insulation interlayer 146, that of the third insulation interlayer 144, that of the second insulation interlayer 132 and/or that of the first insulation interlayer 126. Alternatively, the first to the fifth insulation interlayers 126, 132, 144, 146 and 160 may be formed using different oxides, respectively.

In some example embodiments, the fifth insulation interlayer 160 may be planarized by a planarization process such as a CMP process and/or an etch-back process, so that the fifth insulation interlayer 160 may have a flat upper face.

After forming a sixth photoresist pattern (not illustrated) on the fifth insulation interlayer 160, the fifth insulation interlayer 160 is partially etched using the sixth photoresist pattern as an etching mask. Hence, a third contact hole (not illustrated) is formed through the fifth insulation interlayer 160 to expose the upper electrode 156 of the capacitor 158.

The sixth photoresist pattern is removed from the fifth insulation interlayer 160, and then a fifth conductive layer (not illustrated) is formed on the fifth insulation interlayer 160 to fill the third contact hole. The fifth conductive layer may be formed using a metal and/or a metal compound. For example, the fifth conductive layer may include tungsten, tungsten nitride, titanium, titanium nitride, aluminum, aluminum nitride, titanium aluminum nitride, tantalum, tantalum nitride, copper, etc. Additionally, the fifth conductive layer may be formed by an ALD process, a sputtering process, a CVD process, an evaporation process, etc.

The fifth conductive layer is removed until the fifth insulation interlayer 160 is exposed, so that a first wiring 164 and an upper contact pad 162 are formed. The upper contact pad 162 fills the third contact hole and the first wiring 164 locates on the upper contact pad 162 and the fifth insulation interlayer 160. The first wiring 164 may serve as an additional upper electrode of the capacitor 158.

A sixth conductive layer is formed on the fifth insulation interlayer 160 to cover the first wiring 164. The sixth conductive layer may be formed using a metal and/or a metal compound. For example, the sixth conductive layer may include aluminum, aluminum nitride, tungsten, tungsten nitride, titanium, titanium nitride, titanium aluminum nitride, tantalum, tantalum nitride, copper, etc. The sixth conductive layer may be formed by an ALD process, a sputtering process, a CVD process, an evaporation process, etc. In example embodiments, the sixth conductive layer may be formed using a conductive material substantially the same as or substantially similar to that of the fifth conductive layer. Alternatively, the sixth conductive layer may include a conductive material different from that of the fifth conductive layer.

The sixth conductive layer is etched by a process substantially the same as or substantially similar to that for the fifth conductive layer, such that a second wiring 170 covering the first wiring 162 is formed on the fifth insulation interlayer 160. Therefore, the wiring structure having the first and the second wirings 164 and 170 is provided over the capacitor 158.

FIG. 14 is a plan view illustrating a semiconductor device in accordance with example embodiments.

Referring to FIG. 14, an active region 202 of a substrate 200 is defined by forming an isolation layer 204 on the substrate 200. The substrate 200 may include a semiconductor substrate, an SOI substrate, a GOI substrate, etc.

The isolation layer 204 may be formed on the substrate 200 by an STI process or a thermal oxidation process. The isolation layer 204 may include an oxide such as silicon oxide.

The active region 202 has a first portion and a second portion. The first portion of the active region 202 may extend along a first direction IV and the second of the active region 202 may extend in a second direction V substantially different from the first direction IV. For example, the active region 202 may have a bent line structure or a bar structure. Namely, the first portion and the second portion are bent centering a central portion of the active structure 202 by a predetermined angle.

In example embodiments, the first direction IV may be a left-handed diagonal direction relative to an end of the substrate 200, whereas the second direction V may be a right-handed direction with respect to the end of the substrate 200. For example, the active region 202 including the first and the second portion may have a V-shaped plan structure. One active region 202 may be opposite an adjacent active region 202. That is, an adjacent active region 202 may have an inverse V shape when the active region 202 has the V-shape. The first portion of the active region 202 may be adjacent to a second portion of another active region 202 centering a bit line 234.

A word line 218 is provided on the substrate 200. The word line 218 may have a construction substantially the same as or substantially similar to that of the word line 218 described with reference to FIG. 5. The word line 218 may extend along a third direction VI inclined relative to the first and the second directions IV and V by a predetermined angle. In example embodiments, two word lines 218 may cross over the active region 202. One of the word lines 218 may cross over the first portion of the active region 202, and the other of the word lines 218 may cross over the second portion of the active region 202. When the word line is formed on the substrate 200, the central portion and end portions of the active region 202 may be exposed.

A first impurity region (not illustrated) is formed at the central portion of the active region 202, and second impurity regions (not illustrated) are formed at end portions of the active region 202. The first and the second impurity regions may be formed by a process substantially the same as or substantially similar to that of the first and the second impurity regions 120 and 122 described with reference to FIG. 5. Further, each of the first and the second impurity regions may include sub-regions having different impurity concentrations.

A first insulation interlayer (not illustrated) covering the word line 218 is provided on the substrate 200. The first insulation interlayer may include an oxide such as silicon oxide. A contact pad (not illustrated) is disposed on the first impurity region through the first insulation interlayer. The contact pad may be formed by a process substantially the same as or substantially similar to that of the contact pad 128 described with reference to FIG. 7. The contact pad may include doped polysilicon, metal and/or metal compound.

After a second insulation interlayer (not illustrated) is positioned on the first insulation interlayer, the bit line 234 and a bit line contact pad 238 are formed on the contact pad and the first insulation interlayer. The bit line 234 and the bit line contact pad 238 may be formed using doped polysilicon, metal and/or metal compound by a sputtering process, an ALD process, a CVD process, an evaporation process, etc. The bit line 234 makes an electrical contact with the first impurity region through the bit line contact pad 238 and the contact pad.

In example embodiments, the bit line 234 may extend on the first insulation interlayer along a fourth direction VII substantially perpendicular to the third direction VI. The first and the second portions of the active region 202 may be symmetrical to each other centering the bit line 234. The bit line 234 may cross over the central portion of the active region 202. Further, the bit line 234 may partially cross over the first and the second portions of the active region 202.

In example embodiments, two bit line contact pads 138 may be disposed along the bit line 234 by the one pitch of a memory cell of the semiconductor device. Additionally, one bit line contact pad 138 may be positioned along the word line 218 by the two pitches of the memory cell of the semiconductor device.

A third insulation interlayer (not illustrated) and a fourth insulation interlayer (not illustrated) are provided on the bit line 234 and the first insulation interlayer, a contact plug 248 is formed through the fourth to the first insulation interlayers. The contact plug 248 may be formed using doped polysilicon, metal and/or metal nitride by a sputtering process, an ALD process, a CVD process, an evaporation process, etc. The contact plug 248 is positioned on the second impurity region.

According to example embodiments, a first distance D1 between adjacent bit lines 234 may be increased while a second distance D2 between adjacent word lines 218 may be reduced in comparison with those of the conventional folded bit line type semiconductor device. Thus, the number of contact plugs may be decreased and also the loading capacitance of the bit line 234 may be considerably decreased, thereby improving the sensing margin of the semiconductor device.

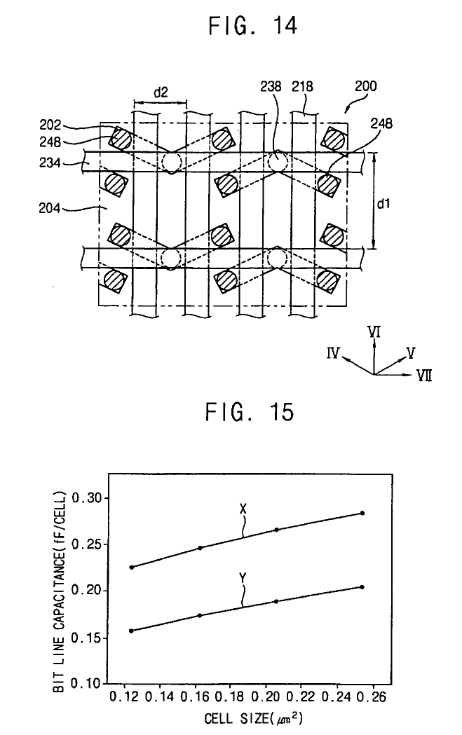

FIG. 15 is a graph illustrating capacities of capacitors relative to the cell sizes of the conventional semiconductor device and a semiconductor device according to example embodiments. In FIG. 15, “X” indicates the bit line capacitance of the conventional semiconductor device, and “Y” denotes the bit line loading capacitance of the semiconductor device having the opened bit line structure device according to example embodiments. The semiconductor device according to example embodiments includes a substrate having an active region, transistors having impurity regions and word lines, bit lines symmetrically disposed centering the impurity regions, and capacitors disposed over the bit lines. In the semiconductor device having the opened bit line structure, two bit line contact pads are disposed between adjacent bit lines by the one pitch of the memory cell of the semiconductor device, and further one bit line contact pad is positioned between adjacent word lines by the two pitches of the memory cell.

As illustrated in FIG. 15, the bit line loading capacitances X and Y of both semiconductor devices are increased according the cell sizes thereof are augmented. However, the bit line loading capacitance Y of the semiconductor device according to example embodiments is relatively smaller than the bit line loading capacitance X of the conventional semiconductor device even though both of the semiconductor devices have the same cell size. Therefore, the semiconductor device according to example embodiments may have sensing margin considerably larger than that of the conventional semiconductor device. For example, the conventional semiconductor device has the bit line loading capacitance of about 0.23 fF/cell to about 0.27 fF/cell whereas the semiconductor device according to example embodiments has the bit line loading capacitance of about 0.16 fF/cell to about 0.20 fF/cell. Hence, the semiconductor device may have the bit line loading capacitance reduced by about 30 percent of that of the conventional semiconductor device.

In the semiconductor device having a ferroelectric capacitor according to example embodiments, the sensing margin of the semiconductor device may be proportional to the capacitance of the capacitor and may be inversely proportional to the capacitance of the bit line. The capacitance of the bit line may be reduced according as the distance between adjacent bit lines is increased.

As described above, the capacitance between the bit lines of the semiconductor device having the opened bit line structure may be considerably reduced in comparison with that of the conventional semiconductor device having the folded bit line structure. For example, the capacitances between adjacent bit lines and between the contact plug and the bit line may be greatly reduced because the distance between adjacent bit lines is increased relative to that of the conventional semiconductor device. Therefore, the semiconductor device having the opened bit line structure may ensure considerably enhanced sensing margin.

According to example embodiments, contact plugs may be symmetrically disposed centering two adjacent word lines and one bit line, so that the distance between adjacent bit lines may be increased. Thus, the capacitance between adjacent bit lines and the capacitance between the bit line and the contact plug may be effectively reduced. When a semiconductor device includes the above-described construction, the semiconductor device may have considerably improved sensing margin.

The foregoing is illustrative of example embodiments, and is not to be construed as limiting thereof. Although a few example embodiments have been described, those skilled in the art will readily appreciate that many modifications are possible in the example embodiments without materially departing from the novel teachings and advantages of example embodiments. Accordingly, all such modifications are intended to be included within the scope of example embodiments as defined in the claims. In the claims, means-plus-function clauses are intended to cover the structures described herein as performing the recited function and not only structural equivalents but also equivalent structures. Therefore, it is to be understood that the foregoing is illustrative of example embodiments and is not to be construed as limited to the specific embodiments disclosed, and that modifications to the disclosed example embodiments, as well as other example embodiments, are intended to be included within the scope of the appended claims. The invention is defined by the following claims, with equivalents of the claims to be included therein.

1. A semiconductor device comprising:
a substrate including an active region that has end portions extending in a first direction and a central portion extending in a second direction inclined relative to the first direction;
a first impurity region disposed at the central portion of the active region;
second impurity regions disposed at the end portions of the active region;
a word line extending along a third direction substantially perpendicular to the first direction; and
a bit line extending in the first direction, the bit line being electrically connected to the first impurity region.

2. The semiconductor device of claim 1, wherein the second impurity regions are symmetrically disposed centering one bit line.

3. The semiconductor device of claim 1, wherein the second impurity regions are symmetrically disposed centering two adjacent word lines.

4. The semiconductor device of claim 1, further comprising:
an insulating interlayer disposed between the word line and the bit line; and
a contact pad making contact with the first impurity region through the insulation interlayer.

5. The semiconductor device of claim 1, wherein further comprising:
an additional insulation interlayer disposed on the bit line;
a contact plug making contact with the second impurity region; and
a capacitor disposed on the additional insulation interlayer and the contact plug.

6. The semiconductor device of claim 5, wherein two contact plugs are symmetrically disposed centering two adjacent word lines and one bit line.

7. The semiconductor device of claim 1, wherein the word line comprises:
a gate insulation layer pattern on the substrate;
a gate electrode on the gate insulation layer pattern; and
a gate mask on the gate electrode.

8. A semiconductor device comprising:
a substrate having an active region that includes a first portion extending along a first direction, a second portion extending along a second direction inclined relative to the first direction, and a central portion between the first and the second portions;
a first impurity region disposed at the central portion of the active region;
second impurity regions disposed at ends of the first and the second portions of the active region;
a word line extending along a third direction substantially inclined relative to the first and the second directions; and
a bit line extending along a fourth direction substantially perpendicular to the third direction, the bit line being electrically connected to the first impurity region.

9. The semiconductor device of claim 7, wherein the second impurity regions are symmetrically disposed centering two adjacent word lines and one bit line.

10. The semiconductor device of claim 7, wherein the active region is symmetrical to an adjacent active region centering the bit line.

11. The semiconductor device of claim 7, wherein the ends of the first and the second portions of the active region are symmetrical to each other centering two adjacent word lines.

12. The semiconductor device of claim 7, further comprising:
a contact pad disposed on the first impurity region;
a first insulation interlayer disposed on the contact pad and the word line;
a second insulation interlayer disposed on the first insulation interlayer and the first insulation interlayer; and
a bit line contact pad disposed on the contact pad through the second insulation interlayer.

13. The semiconductor device of claim 12, further comprising:
a third insulation interlayer disposed on the bit line and the second insulation interlayer;
a contact plug disposed on the second impurity region through the first, the second and the third insulation interlayers; and
a capacitor disposed on the contact plug and the third insulation interlayer.

14-20. (canceled)
